(19) United States
(12) Patent Application Publication
(10) Pub. No.: US 2015/0237762 A1
(43) Pub. Date: Aug. 20, 2015

(54) INTEGRATED THERMAL MANAGEMENT SYSTEM

(71) Applicant: Raytheon Company, Waltham, MA (US)

(72) Inventors: Brendon R. HOLT, Tucson, AZ (US); Teresa J. CLEMENT, Tucson, AZ (US)

(21) Appl. No.: 14/627,384

(22) Filed: Feb. 20, 2015

Related U.S. Application Data
(60) Provisional application No. 61/942,230, filed on Feb. 20, 2014.

(51) Int. Cl. H05K 7/20; B23P 15/26

(52) U.S. Cl. CPC H05K 7/209; B23P 15/26; H05K 7/20336

(57) ABSTRACT

A thermal management system for a heat generating electrical component and a method of making such a thermal management system. Additive manufacturing is used to form at least a portion of the thermal management system as a unitary, monolithic structure. Such a structure maximizes heat transfer by reducing or eliminating thermal interfaces between the components of the thermal management system. The use of additive manufacturing also allows for the production of varying thermal management system geometries that are not possible with conventional methods.

### FIELD OF INVENTION

The present invention relates generally to the management of thermal energy generated by electronics systems, and more particularly to an integrated thermal management system for efficiently and cost-effectively routing and controlling the thermal energy generated by electronic systems.

### BACKGROUND

Heat generation is a significant concern with complex electronic components such as integrated circuits (ICs). The amount of heat generated by an IC is related to the number of transistors on the device as well as the operating speed of the transistors. As transistor density and operating speed increase, heat generation increases. Because IC performance and reliability decrease as temperature increases, it is important that an IC has an adequate thermal management system for dissipating heat from the IC environment.

### SUMMARY OF INVENTION

A thermal management system draws heat from the IC, thereby maintaining lower operating temperatures for the IC and enabling improved operation and longer chip life. Conventional thermal management systems use some combination of thermal interposers, heat spreaders and heat dispersion elements to form a low thermal resistance path between the IC and the ambient environment.

Conventional thermal interposers are typically made of a high thermal conductivity material. They are often used to improve the heat flow path from an IC or group of ICs to a heat spreader.

Conventional heat spreaders are typically made of a high thermal conductivity material (e.g., copper, aluminum, high thermal conductivity plastic). Heat spreaders typically have a smooth surface (a “mating surface”) that is placed in thermal contact with the IC, often via an interposer, and a body that absorbs heat from the IC (“a heat sink”). Heat may be removed from the heat spreader by heat dispersion elements such as heat pipes, phase-change cooling, and/or other features.

Heat pipes are passive, closed heat dispersion elements that are used to transport heat away from a heat source, such as an IC. The typical heat pipe is an enclosed tube-like structure or other enclosed package that is typically made of metal where the interior surface of the enclosure has a wicking structure. The wicking structure moves a coolant (working fluid) in a liquid phase from the sink (condenser) to the source (evaporator) by means of capillary action. The center of the heat pipe enclosure is open and free of obstruction. The working fluid moves through the wick to the evaporator, in the opposite direction of the gas phase that moves in the open space to the condenser. At the hot end of the heat pipe, a phase change from liquid into vapor occurs, while at the cool side, the phase change from vapor into liquid occurs. Heat transport is accomplished by the removal of heat through the latent heat of evaporation and cooling through the latent heat of condensation. The center of the heat pipe continuously transports the vapor via a pressure differential between the hot and cold ends of the heat pipe. The wicking material passively transports the liquid thus making a cycle that continuously moves heat away from the hot end of the heat pipe. Bending or shaping of conventional heat pipes, or creating intersections within conventional heat pipes, can result in mechanical damage to the interior wicking structure, which can affect the operation of the heat pipe. Therefore, the geometry of conventional heat pipes is generally limited to straight or modestly deformed, unbranched arrangements in order to maintain the structural integrity of the wicking structure.

Phase change chambers are heat dispersion elements that are used to store latent heat in a phase change material (PCM). PCMs undergo a phase transition when heat is supplied or removed, e.g., a transition from the solid to the liquid phase (melting) or from the liquid to the solid phase (solidification) or a transition between a low-temperature and high-temperature phase or between a hydrated and a de-hydrated phase or between different liquid phases. If heat is supplied to or removed from a phase change material, on reaching the phase transition point the temperature remains constant until the material is completely transformed. The heat supplied or released during the phase transition, which causes no temperature change in the material, is known as latent heat.

The phase change chamber is charged by transfer of heat (thermal energy) from a medium which releases heat across an interface into the phase change material where the heat is stored, and discharged by transfer of heat from the phase change material across the interface to a medium which is heated. The medium from/to which heat is transferred can be, for example, paraffin wax, water or steam, air, helium or nitrogen. The heat exchange interface can consist, for example, of the walls of heat exchange tubes passed through by a medium from/to which heat is transferred, or of heat exchanger plates over which a medium flows from/to which heat is transferred.

Due to the low thermal conductivity of most phase change materials, they are typically combined with an auxiliary component with high thermal conductivity, e.g., graphite flakes or sheets. The phase change chamber may also be constructed to minimize the distance over which heat must be transferred within the bulk of the phase change material. This can be done, for example, by increasing the surface area of the heat exchange interface through the use of fins or other protrusions on the inner walls of the phase change chamber or adding a conduction lattice internal to the chamber.

In typical thermal management systems, the individual components (e.g., interposer, heat spreader and heat dispersion elements) are combined to create a path of low thermal resistance from the IC to the ambient environment. However, the thermal interface surfaces of these components are irregular, either on a gross or a microscopic scale. When the interface surfaces are mated, pockets or void spaces occur there between. These pockets reduce the overall surface area contact within the interface which, in turn, reduces the efficiency of the heat transfer there though.

To improve the efficiency of the heat transfer through the interface, a layer of a thermally-conductive material typically is interposed between the components to fill in surface irregularities and eliminate air pockets. These thermal interface materials (TIMs) typically consist of thermally-conductive particulate fillers dispersed within greases, waxes, or cured polymer sheets.

Grease and wax TIMs generally are not self-supporting or otherwise form-stable at room temperature and are difficult to apply to interface surfaces in a clean manner. For ease of handling, these materials are sometimes provided in film form. To do so, a substrate, web or other carrier is used, which introduces another interface layer in or between which additional air pockets may be formed. Use of grease and wax TIMs typically involves hand application or lay-up by the electronics assembler which increases manufacturing costs.

Cured polymer sheet TIMs are form-stable at room temperature and more easily applied. However, heavy fastening elements such as springs, clamps, and the like are often required to apply enough force to conform these materials to the interface surfaces to attain enough surface contact for efficient thermal transfer.

Additive manufacturing (also known as solid free form fabrication (SFF) or free form fabrication (FFF), rapid prototyping, rapid manufacturing, layered manufacturing or three-dimensional printing) involves joining materials to make objects from 3D model (such as computer-aided design (CAD)) data. In a common form, the object is built up layer upon layer as part of a printing process. In this way, it differs from traditional (also known as subtractive) manufacturing where the process starts with a larger part that has excess material subsequently stripped away. With additive manufacturing, the fabrication machine reads in the model data and then lays down successive layers of liquid, powder or related material such that it builds up the object from a series of cross sections. The properties of the materials of the individual layers are such that they are joined or fused to create the final shape. One significant advantage to additive manufacturing is its ability to create almost any shape or geometric feature, while another is the potential for reduction in waste.

It therefore will be appreciated that an improved thermal management system would be well-received by the electronics industry. Especially desired would be a thermal management system in which thermal interfaces are reduced or eliminated. Also especially desired would be a thermal management system including a heat pipe with a curved and/or branched geometry.

According to one aspect of the invention, there is provided a method of manufacturing a thermal management system for a heat generating electrical component that includes the steps of receiving data corresponding to a three-dimensional structure; and driving a forming device to deposit a heat conducting material to form the three-dimensional structure represented by the data; wherein the three-dimensional structure includes the thermal management system for removing heat from the heat generating electrical component.

The method further includes the step of generating the data before receiving the data.

The method further includes the step of rendering the data before receiving the data.

The method further includes the step of sending the data before receiving the data.

The forming device may be a three-dimensional printer.

The heat conducting material may be a metal or a plastics-based synthetic material.

The data corresponding to a three-dimensional structure may be CAD data.

The thermal management system may include a unitary structure, and the unitary structure may include a thermal interposer and a heat spreader.

The thermal management system may include a PCM chamber, either as part of the unitary structure or encapsulated within the unitary structure.

The thermal management system may include a heat pipe, either as part of the unitary structure or encapsulated within the unitary structure.

The heat pipe may include multiple branches.

At least a portion of the heat pipe may be curved.

According to another aspect of the invention, there is provided a thermal management system for a heat generating electrical component that includes a unitary, monolithic structure including a thermal interposer and a heat spreader formed using additive manufacturing.

The thermal management system may include a heat pipe.

The heat pipe may be formed as an integral part of the unitary, monolithic structure.

The heat pipe may be encapsulated within the unitary, monolithic structure.

The heat pipe may include multiple branches.

At least a portion of the heat pipe may be curved.

The thermal management system may include a PCM chamber.

The PCM chamber may be formed as an integral part of the unitary, monolithic structure.

The PCM chamber may be encapsulated within the unitary, monolithic structure.

The thermal management system may be made from a metal or from a plastics-based synthetic material.

The foregoing and other features of the invention are hereinafter described in greater detail with reference to the accompanying drawings.

### BRIEF DESCRIPTION OF THE DRAWINGS

FIG. 1 is a cross-sectional view of a thermal management system on a heat generating electrical component according to an embodiment of the present invention.

FIG. 2 is a cross-sectional view of a thermal management system on a heat generating electrical component according to an embodiment of the present invention.

FIG. 3 is a cross-sectional view of a thermal management system on a heat generating electrical component according to an embodiment of the present invention.

FIG. 4 is a cross-sectional view of a thermal management system on a heat generating electrical component according to an embodiment of the present invention.

### DETAILED DESCRIPTION

Various forms of thermal management systems can be made using additive manufacturing. Significantly, the use of additive manufacturing allows for the reduction or elimination of thermal interface surfaces between the various components of a thermal management system. This reduction or elimination of thermal interfaces leads to an increase in cooling performance over conventional thermal management systems. Additionally, the use of additive manufacturing allows for the production of varying thermal management system geometries that are not possible with conventional methods.

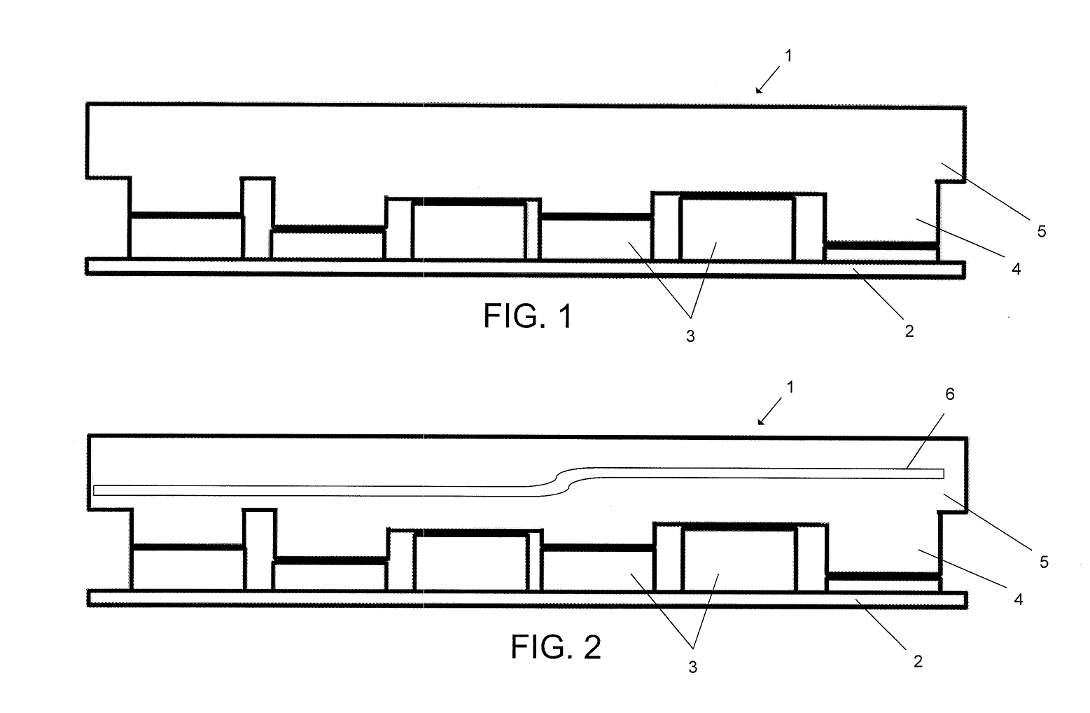

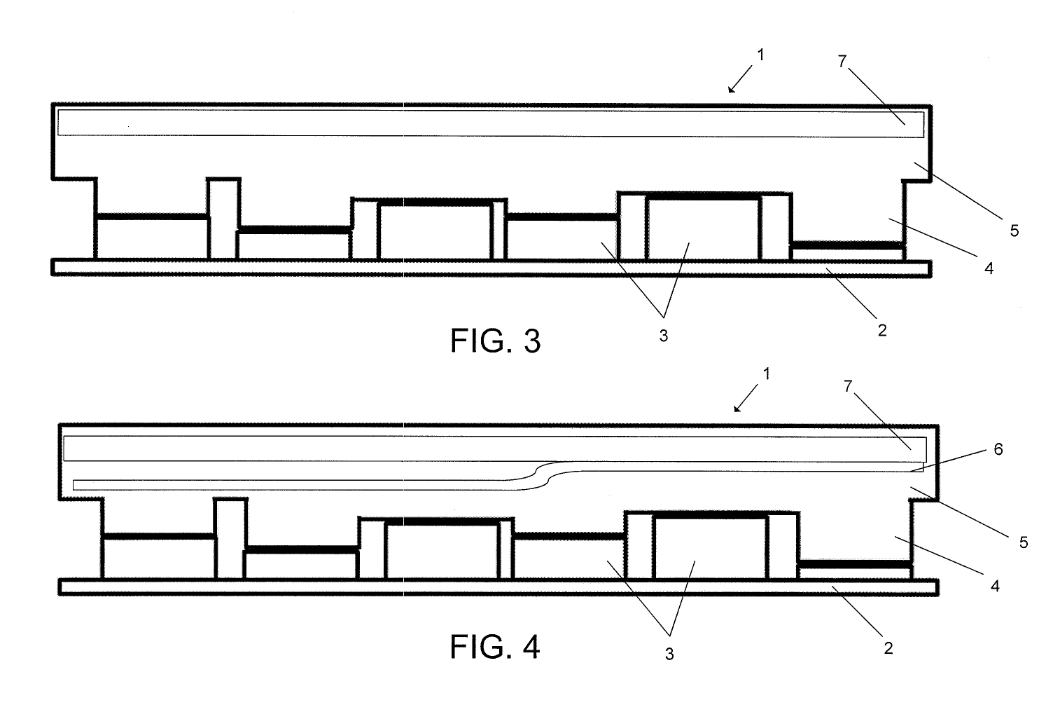

Referring to FIGS. 1-4, various embodiment of a thermal management system 1 according to the present invention is shown. Thermal management system 1 moves or otherwise transfers heat away from a heat generating electrical component. In certain embodiments, the heat generating electrical component may be a component 3, such as an integrated circuit (IC), located on a printed wiring board 2. Thermal management system 1 includes thermal interposer 4 and heat spreader 5. Thermal interposer 4 and heat spreader 5 are formed using additive manufacturing such that they are a unitary, monolithic structure having no joints or seams. In certain embodiments, additive manufacturing may include three-dimensional printing. Thermal management system 1 may be made using any material or combination of materials having sufficient thermal conductivity to act as a thermal management system. In certain embodiments, the minimum thermal conductivity of the material used to make the thermal management system may be on the order of 200 W/(mK). In certain embodiments, the minimum thermal conductivity of the material used to make the thermal management system may be on the order of 400 W/mK. Potential materials include thermally conductive plastics, metals, metal alloys, graphene, and various combinations thereof.

In certain embodiments, thermal management system 1 may also include heat pipe 6. In some embodiments, heat pipe 6 may be formed as a unitary, monolithic structure with thermal interposer 4 and heat spreader 5 using additive manufacturing. The working fluid may be added to the heat pipe in a separate charging step once the thermal management system has been formed. This charging step may include injecting the working fluid into the heat pipe through a pre-formed hole in the thermal management system and then sealing the hole. In other embodiments, heat pipe 6 may be encapsulated within the unitary, monolithic structure including thermal interposer 4 and heat spreader 5. This encapsulation may be accomplished by, for example, pausing the additive manufacturing at a certain point, inserting a pre-fabricated heat pipe 6 into the partially completed unitary, monolithic structure, and then restarting the additive manufacturing. In certain embodiments, heat pipe 6 may include multiple heat flow paths or branches. Heat pipe 6 may also include curved portions. These branches and/or curved portions may be formed in the heat pipe using additive manufacturing. This would allow the wicking structure to be tailored to accommodate the branches and/or curved portions without suffering the mechanical damage that typically results when a heat pipe is shaped or deformed.

In certain embodiments, thermal management system 1 may also include PCM chamber 7. In some embodiments, PCM chamber 7 may be formed as a unitary, monolithic structure with thermal interposer 4 and heat spreader 5 using additive manufacturing. The PCM may be added to the PCM chamber in a separate charging step once the thermal management system has been formed. This charging step may include injecting the PCM into the PCM chamber through a pre-formed hole in the thermal management system and then sealing the hole. In other embodiments, PCM chamber 7 may be encapsulated within the unitary, monolithic structure including thermal interposer 4 and heat spreader 5. This encapsulation may be accomplished by, for example, pausing the additive manufacturing at a certain point, inserting a pre-fabricated PCM chamber into the partially completed unitary, monolithic structure, and then restarting the additive manufacturing.

In certain embodiments, thermal management system 1 may include heat pipe 6 and PCM chamber 7. In some embodiments, one or both of heat pipe 6 and PCM chamber 7 may be formed as a unitary, monolithic structure with thermal interposer 4 and heat spreader 5 using additive manufacturing. The working fluid may be added to the heat pipe in a separate charging step once the thermal management system has been formed. This charging step may include injecting the working fluid into the heat pipe through a pre-formed hole in the thermal management system and then sealing the hole. The PCM may be added to the PCM chamber in a separate charging step once the thermal management system has been formed. This charging step may include injecting the PCM into the PCM chamber through a pre-formed hole in the thermal management system and then sealing the hole. In certain embodiments, heat pipe 6 may be integrated with PCM chamber 7 such that some portion of heat pipe 6 lies within the PCM chamber and is in direct thermal contact with the PCM. In certain embodiments, one or both of heat pipe 6 and PCM chamber 7 may be encapsulated within the unitary, monolithic structure including thermal interposer 4 and heat spreader 5. This encapsulation may be accomplished by, for example, pausing the additive manufacturing at a certain point, inserting a pre-fabricated PCM chamber 7 and/or heat pipe 6 into the partially completed unitary, monolithic structure, and then restarting the additive manufacturing.

Thermal management system 1 may be manufactured by receiving data corresponding to a three-dimensional structure and driving a forming device to deposit a heat conducting material to form the three-dimensional structure represented by the data, wherein the three-dimensional structure is the thermal management system 1. In certain embodiments, the data may be generated, rendered and/or sent before it is received. In some embodiments, the forming device may include a three-dimensional printer. In some embodiments, the heat conducting material may be a thermally conductive plastic, metal, metal alloy, graphene, or some combination thereof. In certain embodiments, the data may be CAD data.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

1. A method of manufacturing a thermal management system for a heat generating electrical component, the method comprising: receiving data corresponding to a three-dimensional structure; and
driving a forming device to deposit a heat conducting material to form the three-dimensional structure represented by the data, wherein the three-dimensional structure comprises the thermal management system for removing heat from the heat generating electrical component.

2. The method of claim 1, further comprising generating the data before receiving the data.

3. The method of claim 1, further comprising rendering the data before receiving the data.

4. The method of claim 1, further comprising sending the data before receiving the data.

5. The method of claim 1, wherein the forming device comprises a three-dimensional printer.

6. The method of claim 1, wherein the heat conducting material comprises one or more materials from the group of thermally conductive plastics, metals, metal alloys and graphene.

7. The method of claim 1, wherein the data corresponding to a three-dimensional structure is CAD data.

8. The method of claim 1, wherein the thermal management system comprises a unitary structure, wherein the unitary structure comprises a thermal interposer and a heat spreader.

9. The method of claim 8, wherein the thermal management system comprises a PCM chamber.

10. The method of claim 9, wherein the PCM chamber is encapsulated within the unitary structure.

11. The method of claim 9, wherein the unitary structure comprises a PCM chamber.

12. The method of claim 8, wherein the thermal management system comprises a heat pipe.

13. The method of claim 12, wherein the heat pipe is encapsulated within the unitary structure.

14. The method of claim 12, wherein the unitary structure comprises a heat pipe.

15. The method of claim 12, wherein the heat pipe comprises multiple branches.

16. The method of claim 12, wherein at least a portion of the heat pipe is curved.

17. A thermal management system for a heat generating electrical component comprising:
a unitary, monolithic structure comprising a thermal interposer and a heat spreader; wherein the thermal management system is formed using additive manufacturing.

18. The thermal management system of claim 18, wherein the thermal management system comprises a heat pipe.

19. The thermal management system of claim 19, wherein the heat pipe is formed as an integral part of the unitary, monolithic structure.

20. The thermal management system of claim 19, wherein the heat pipe is encapsulated within the unitary, monolithic structure.

21. The thermal management system of claim 19, wherein the heat pipe comprises multiple heat flow paths.

22. The thermal management system of claim 19, wherein at least a portion of the heat pipe is curved.

23. The thermal management system of claim 18, wherein the thermal management system comprises a PCM chamber.

24. The thermal management system of claim 24, wherein the PCM chamber is encapsulated within the unitary structure.

25. The thermal management system of claim 24, wherein the unitary structure comprises a PCM chamber.

26. The thermal management system of claim 18, wherein the thermal management system comprises one or more materials from the group of thermally conductive plastics, metals, metal alloys and graphene.
